(19) United States
(12) Patent Application Publication
(10) Pub. No.: US 2009/0088042 A1
(43) Pub. Date: Apr. 2, 2009

(54) Power Source Compartment For An Electronic Device

(75) Inventor: Robert Mark Goszewski, Depew, NY (US)

Correspondence Address: EDELL, SHAPIRO & FINNAN, LLC, 1901 RESEARCH BOULEVARD, SUITE 400, ROCKVILLE, MD, 20850, US

(73) Assignee: Mattel, Inc., El Segundo, CA (US)

(21) Appl. No.: 11/865,900

(22) Filed: Oct. 2, 2007

(51) Int. Cl. H05K 5/00; A63H 33/00

(52) U.S. Cl. 446/227; 174/53

(57) ABSTRACT

The present invention relates to a leak-proof compartment in which a power supply or source may be disposed. The compartment can be utilized in a children's product. In one embodiment, the children's product may include an electronic device for entertaining a child. The leak-proof compartment includes a receptacle having an opening and a cover for closing and sealing the opening. The receptacle is configured to receive the power source and the cover is placed within the opening to seal the compartment. The sealing effect of the cover prevents substances from leaking out of the compartment.

### FIELD OF THE INVENTION

The present invention relates to a compartment for a power source, and in particular, a leak-proof compartment for holding or containing a power source for an electronic device.

### BACKGROUND OF THE INVENTION

Many products include an electronic system that has electrical or electronic features that are powered by a power supply or power source, such as batteries. Such products may receive inputs from a user or child and/or generate outputs such as visual outputs or audible outputs. These products typically include a compartment within which one or more batteries are placed. The compartment typically includes electrical portions or contacts that engage the terminals of the batteries to draw power from the batteries. Current flows through one or more batteries in the power source compartment to energize the electrical or electronic features of the product.

After a period of time, some power sources may fail, particularly if the batteries are old, degraded, or otherwise malfunctioning. The failure of a power source that contains a material, such as acid, that can leak from batteries typically results in the material leaking from the power source compartment. Such materials may contact a person, if the compartment is located in a position or orientation in which contact may occur.

In some products, the power source may be located in a position that is above a region or area in which a child may be placed. Accordingly, when a child is placed in a particular region or area relative to a product, the location of the power source may be above or over the child. In this overhead arrangement of the power source, there may be an increased need for a leak-proof power source compartment.

The overhead arrangement of a power source may be found in infant entertainment devices or products. For example, some children's entertainment products such as child support structures (such as swings, bouncers, cradles, strollers, cribs, playards, etc.) may include a motorized motion mechanism that moves or vibrates a portion of the support structures. One example is a swing that includes a drive mechanism for moving the seat of the swing back and forth. In addition, some children's entertainment products include a frame with a child entertainment device (e.g., an electronic toy bar, an electronic toy tray, etc.). A child entertainment product may include an overhead housing from which audible outputs and/or visual outputs emanate or from which some motorized object moves to entertain the child. In these products, one or both of the motorized motion mechanism and the child entertainment device are located higher than and/or over the child.

There is therefore a need to develop a leak-proof compartment for a power supply. There is also a need to develop a removable cover for a leak-proof compartment that is not dislodged or removed easily.

### SUMMARY OF THE INVENTION

In an embodiment of the present invention, a children's product may include a housing that has a power supply compartment (e.g., a battery compartment). The power supply compartment is in electrical communication with an electronic system of the child entertainment device. The power supply compartment can contain a power supply which is in electrical communication with contacts. Therefore, when the power supply is properly positioned in the power supply compartment, the power supply comes into direct electrical communication with the child entertainment device.

In one embodiment, the power supply compartment has a container which defines a receptacle that is configured to receive the power supply. The container includes an opening through which the power supply may be inserted into the receptacle. In one embodiment, the opening has a perimeter and the container includes a side wall extending around the perimeter of the opening. The power supply compartment may also include a cover including an outer surface, an inner surface opposite the outer surface, and a side surface. The outer surface may be configured to be substantially continuous with an outer surface of the product. The cover includes a perimeter and the side surface extends around the perimeter of the cover.

In one embodiment, the cover includes a separately formed sealing element or sealing element portion that includes an outer surface and an inner surface opposite its outer surface. The sealing element is coupled on the cover so that the sealing element's inner surface engages the side surface of the cover. In another embodiment, the sealing element or sealing element portion can be integrally formed with the cover.

The sealing element may include a plurality of continuous ribs formed in the sealing element outer surface and extending around the sealing element. The ribs are configured to engage the side wall of the container when the cover and sealing element are inserted into the opening of the container. The ribs are configured to seal the container and to frictionally retain the cover on the container and couple the cover to the container. The ribs provide a snug and tight fit between the cover and the container. As a result, any material that may leak from a power supply is safely contained within the power supply compartment.

### BRIEF DESCRIPTION OF THE DRAWINGS

FIG. 1A illustrates a front perspective view of a children's product including an electronic device.

FIG. 1B illustrates a rear perspective view of the product illustrated in FIG. 1 showing a power source compartment.

FIG. 2 illustrates a perspective view of an embodiment of a power source compartment including a container and a battery cover.

FIG. 3 illustrates a perspective view of the container illustrated in FIG. 2.

FIG. 4A illustrates a perspective view of an inner side of the cover illustrated in FIG. 2 with a sealing element on the cover.

FIG. 4B illustrates a perspective view of an outer side of the cover illustrated in FIG. 2 without the sealing element.

FIG. 5A illustrates a perspective view of an embodiment of a sealing element.

FIG. 5B illustrates a cross-sectional view of the sealing element illustrated in FIG. 5A.

FIG. 6A illustrates a perspective view of the cover illustrated in FIG. 2 partially inserted into a receptacle of a container.

FIG. 6B illustrates a perspective view of the cover illustrated in FIG. 2 fully inserted into a receptacle of container.

Like reference numerals have been used to identify like elements throughout this disclosure.

### DETAILED DESCRIPTION OF THE INVENTION

The terms “power source,” “power supply,” and “battery” may be used interchangeably herein to designate any source of power, including but not limited to, any type of batteries or cells. The term “infant support structure” is used to designate any type of structure on which or near which a child can be placed and/or supported, including, but not limited to, a crib, a swing, a playard, a bounce, a highchair. The terms “child entertainment device” and “infant entertainment device” may be used interchangeably herein to designate a product that can be used to entertain a child, particularly because the product includes an output generating system that generates a visual output, an audible output, and/or a tactile output, any of which can entertain a child. The terms “child” and “infant” may be used interchangeably herein.

In one embodiment, a children's product having a leak-proof compartment for retaining a power source is disclosed. The children's product can be any product that includes an electrical or electronic feature that is operable by an electronic system that includes a power source. The product may be a stand-alone product or a product that can be used in combination with another structure or product.

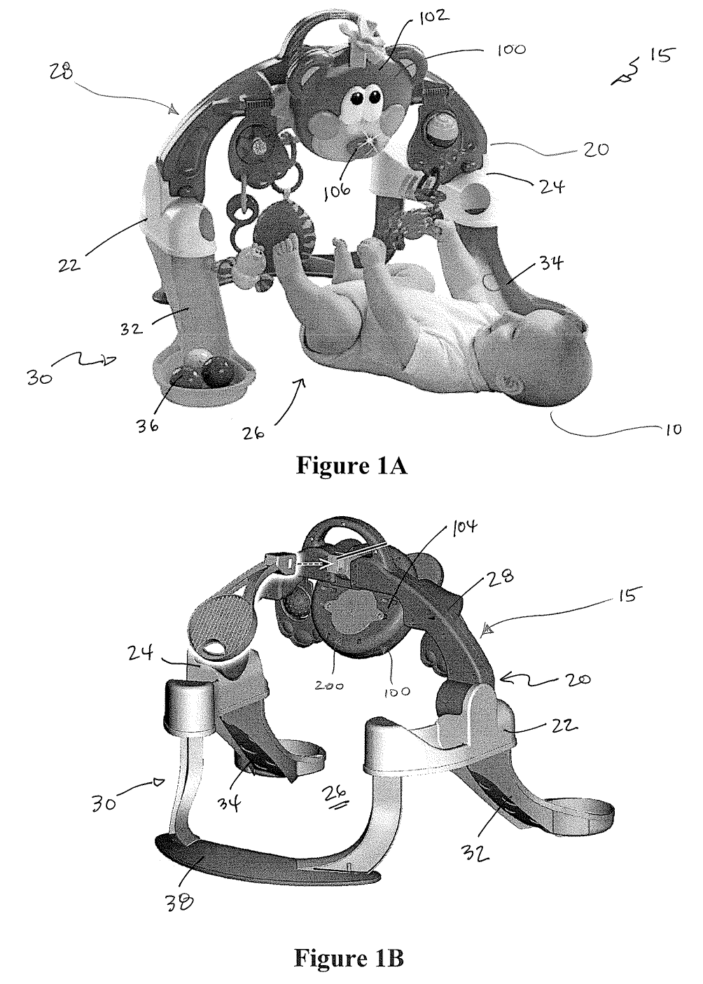

FIGS. 1A and 1B illustrate an embodiment of a children's product. In this embodiment, the product is in the form of a child entertainment device 15 that includes an entertainment component or electronic device 100 for entertaining a child 10. The child entertainment device 15 includes a frame or support member 20 for supporting the electronic device 100 in a position relative to the child 10.

The frame or support member 20 includes a first side portion 22 and a second side portion 24. The first side portion 22 and the second side portion 24 define therebetween an infant receiving region or area 26 in which a child may be placed or located. The frame or support member 20 includes an upper portion 28 that is substantially arcuate and a lower portion 30 that is configured to support the frame 20 on a support surface. The upper portion 28 is pivotally coupled to the lower portion 30 and is selectively disposable in a first or deployed position as shown in FIG. 1A and in a second or retracted position (not shown). The configuration of the upper portion 28 can vary in different embodiments. In this embodiment, the lower portion 30 includes front legs 32 and 34 that are configured to be used with toys, such as balls 36. The lower portion 30 also includes a rear leg 38 that provides support to the frame 20.

In this embodiment, the upper portion 28 is positionable so that it is located over the infant receiving region or area 26. The upper portion 28 includes an electronic portion 100 that is coupled to or supported thereon. The electronic portion 100 includes an electronic system that is configured to receive inputs and an output generating system that is configured to generate audible and/or visual outputs. In one embodiment, the child entertainment device 15 includes one or more switches, such as contact switches or motion switches, that can be closed to provide an input to the system. For example, the device 15 may include a motion sensor or switch, which when closed, causes a visual output device, such as light 106 on the front 102 of device 100, to be illuminated. The electronic system includes a controller, a memory component, and software or programming that controls the functioning of the components of the system. Various outputs, such as audible outputs and visual outputs, can be generated by the device 100.

As illustrated in FIG. 1A, the upper portion 28 with the electronic portion 100 is positioned so that it extends over the child 10 or in close proximity to the child 10. In this position, the electronic device 100 is reachable by the child 10. In other embodiments, the support member 20 can be a fixed frame for supporting the electronic device 100. In addition, the support member 20 can be a frame having a removable connector (not shown) for connecting the electronic device 100 to another children's product such as an infant support structure (e.g., a crib, a highchair, a walker, a bouncer, a swing, a playard etc.).

Many child products include an entertainment system, which, during use, is positioned so that a child can see and/or interact with the system. It can be convenient to position the power source (e.g., batteries) in close proximity to the electronics in the electronic device.

FIG. 1B illustrates a rear view of an embodiment of the child entertainment device 15 showing a power source compartment 200 on a rear surface 104 of the electronic device 100. As shown in FIG. 1A, when the child entertainment device 15 is configured and utilized as a baby gym, the electronic device 100, and thus, the power source compartment 200 can be located directly over an infant receiving region 26. In a children's product that includes an electronic device that is intended to be reached and touched by a child, a leak-proof battery compartment 200 is useful even if the electronic device 100 is not positioned overhead or above an area in which a child may be located. Thus, the power source compartment 200 can be useful regardless of the positioning of the compartment 200.

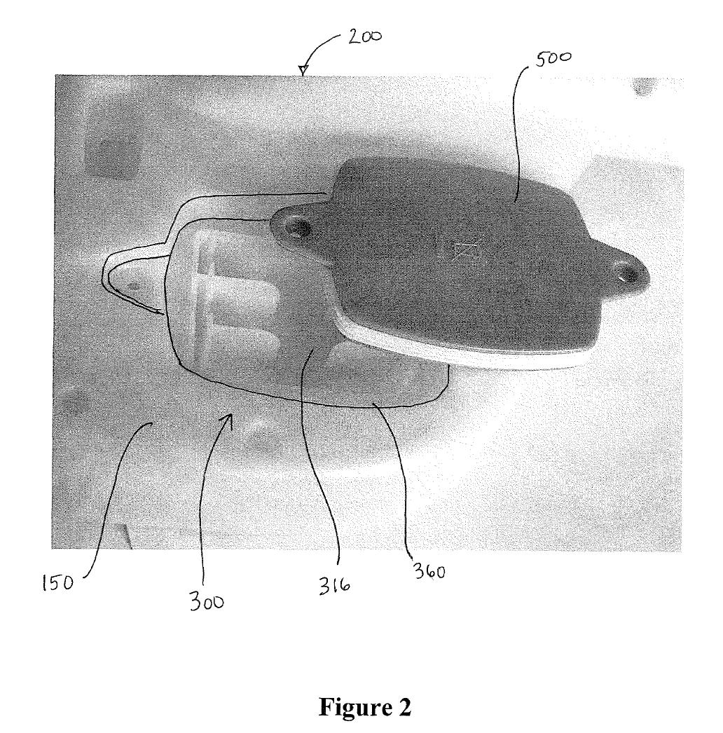

FIG. 2 shows an embodiment of a power source compartment. In this embodiment, the power source compartment 200 is integrally formed with the housing of the electronic device 100. The power source compartment 200 includes a container 300 that is formed in a wall 150 of the electronic device 100. The container 300 can include one or more receptacles 316, each of which is configured to receive a power source, such as a battery, therein. In the illustrated embodiment, the power source compartment 200 can be formed entirely of molded plastic, although other suitable materials may be used. The power source compartment 200 defines an opening 360. In this embodiment, the opening 360 is substantially aligned with the outer surface of the housing or wall 150.

FIG. 2 also shows a cover 500 that is configured to be placed into the compartment opening 360. The cover 500 mates with the opening 360 of the compartment 200 and is configured so that it seals the compartment 200 to prevent or limit the leakage of materials out of the battery compartment 200.

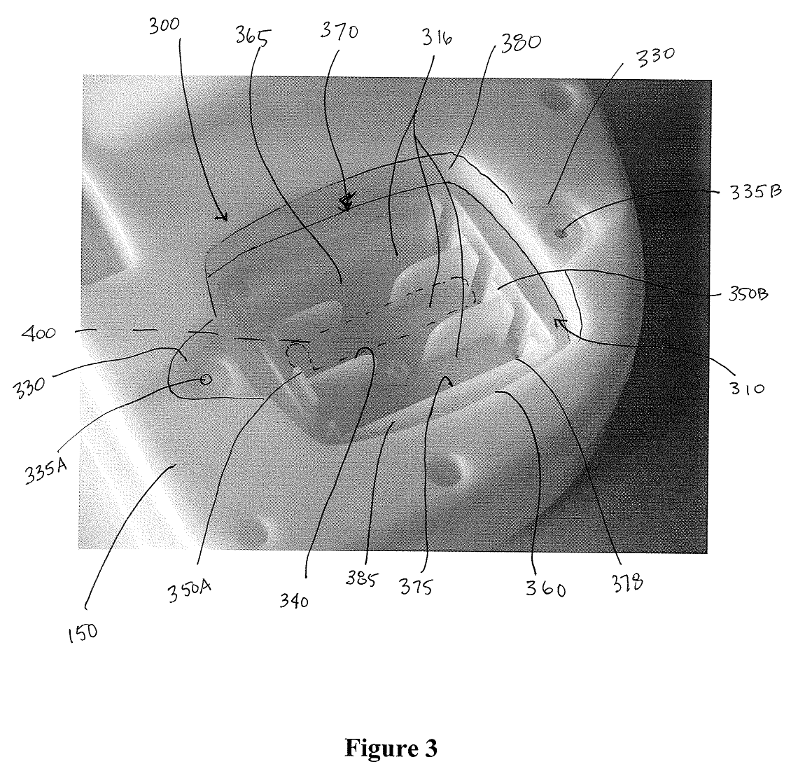

Referring to FIG. 3, an embodiment of a container 300 is illustrated. In this embodiment, the container 300 includes three individual power source receptacles 316. Outward from the receptacles 316 is a cover receptacle 310 which is an opening or area in which the cover 500 can be inserted. In this implementation, the cover receptacle 310 is larger than the power source receptacles 316. Each power source receptacle 316 is configured to receive a battery 400 or another power source. The area of the power source receptacles 316 is further defined by a receptacle sidewall 375 which extends around an outer perimeter 378 of the power source receptacles 316. A power source 400 can be located in a receptacle 316 defined by side dividers 340, which can secure a power source therebetween. Each battery receptacle 316 includes end stops, such as 350A and 350B in FIG. 3, proximate to which a contact is located, and which collectively secure a battery 400 along its length. Each receptacle 316 is defined in part by a battery compartment floor 365 as well. The sidewall 375, the side dividers 340, the end stops 350A, 350B and the battery compartment floor 365 collectively define at least one battery receptacle 316 for securely positioning a battery 400. Even though the illustrated embodiment discloses multiple battery receptacles 316, as few or as many as are desired may be included.

Each battery receptacle 316 includes a conventional electrical portion (not shown). The electrical portion contacts the battery so that current from the battery flows through the electrical portion to a control circuit in the electronic device. The battery receptacle 316 is composed of a moldable material, such as plastic, which is a poor conductor of electricity. A sealing material may be used to prevent leakage between the electrical portions and the battery receptacle 316. Any sealing material with adhesive qualities may be used (e.g., silicone).

As mentioned above, a cover receptacle 310 overlays the battery receptacle 316. In the illustrated embodiment, the cover receptacle 310 is countersunk below the device wall 150. As a result, when the cover 500 is inserted into the cover receptacle 310, the outer surface of the cover 500 aligns with the device wall 150 to provide a flat profile of the battery compartment 200.

The cover receptacle 310 is defined by a battery compartment opening 360 in the device wall 150 that extends around a battery compartment perimeter 370. A cover side wall 380 abuts the compartment opening 360 along the battery compartment perimeter 370. In addition, a cover stop surface 385 abuts and extends generally perpendicular to the cover sidewall 380. Together, the cover sidewall 380 and the abutting cover stop surface 385, form the primary structure defining the cover receptacle 310.

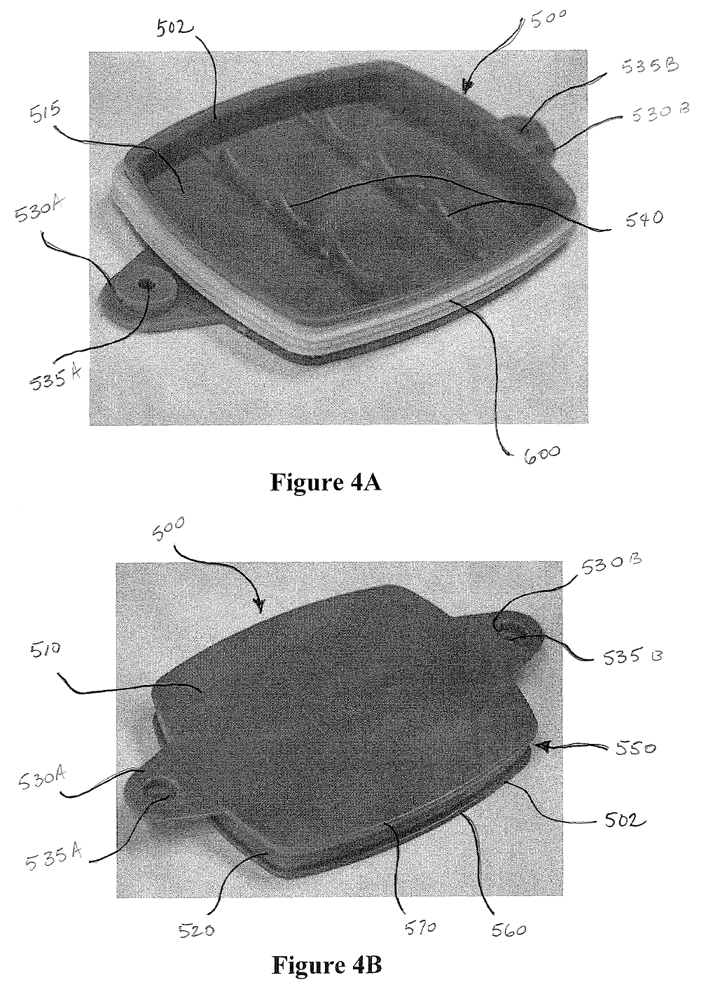

FIGS. 4A and 4B each illustrate perspective views of an embodiment of the cover 500. Specifically, FIG. 4A illustrates the inner surface 515 of the cover 500 and shows a several cover restraints 540 for securing multiple power sources 400 in place in the receptacles 316. FIG. 4B illustrates the outer surface 510 of cover 500 which is visible when the cover 500 is coupled to the container 300. FIG. 4A and 4B also show that cover 500 includes restraint tabs 530A, 530B having openings 535A, 535B therein for receiving connectors, such as screws, for fastening the cover 500 to the container 300. To further ensure that the cover 500 is secured to the container 300, fasteners (e.g., screws, not shown) may be driven through the fastener openings 535A, 535B of the restraint tabs 530A, 530B into the receptacle fastener openings 335A and 335B in the tab recesses 330.

Referring to FIG. 4A, a sealing element 600 is illustrated as extending around the cover 500. Referring to FIG. 4B, the cover 500 includes a groove 550 that extends around the perimeter of the cover 500. In this embodiment, the groove 550 is defined by an inner flange 560, an outer flange 570 and a side surface 520, all of which collectively form a body portion 502. While the side surface 520 is substantially planar, in different embodiments, the side surface of the groove may have a curved or otherwise non-planar configuration. The body portion 502 includes the side surface 520. The perimeter of the cover 500 corresponds to a perimeter of the body portion 502 of the cover 500. In this embodiment, the ribs of the sealing element 600 extend outwardly beyond the perimeter of the body portion 502 of the cover 500. It is noted that the restraint tabs 530A, 530B extend outwardly for a portion of the perimeter of the cover 500. The body portion 502 is the portion of the cover 500 that is configured to contact the side wall of the container 300.

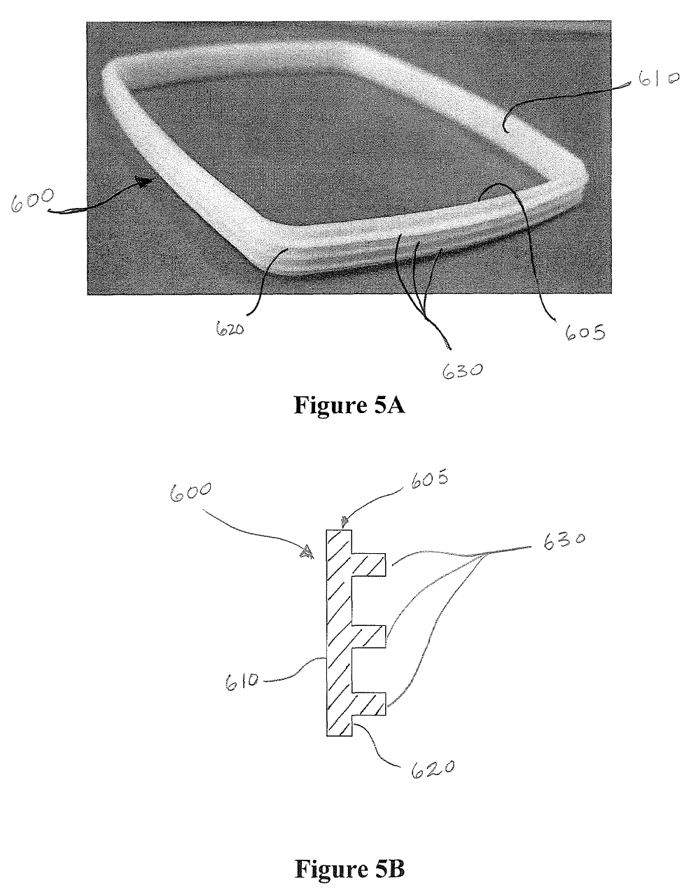

Referring to FIG. 5A, an embodiment of a sealing element is illustrated. In this embodiment, the sealing element 600 is composed of a flexible, elastic material such as rubber, although other elastic materials may be used. Sealing element 600 is a continuous member that forms a circle or loop. The sealing element 600 includes several ribs 630.

Referring to FIG. 5B, a cross-sectional view of the sealing element 600 is illustrated. As shown, the sealing element 600 includes a body or ring 605 that has an inner surface 610 and an outer surface 620. Several ribs 630 extend outwardly from the outer surface 620 of the body 605. The inner surface 610 of the sealing element 600 defines an inner perimeter that is sized slightly smaller that the outer perimeter defined by the side surface 520 of the cover 500. This difference in size is to ensure that there is significant contact force between the inner surface 610 of the sealing element 600 and the side surface 520 of the cover 500. This contact force develops a frictional sealing force between the inner surface 610 and the side surface 520 to prevent leakage between the inner surface 610 and the side surface 520. In other embodiments, the shape, size and configuration of the ribs 630 can vary and in particular, the ribs 630 can have a point-shaped end instead of a block-shaped end.

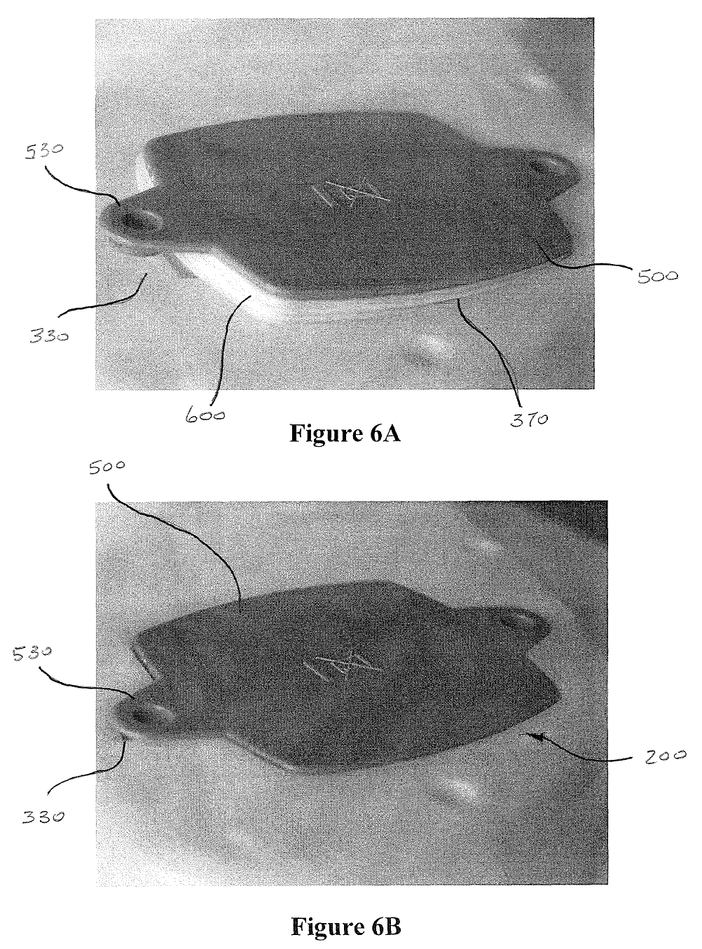

When the cover 500 and the sealing element 600 are assembled as shown in FIG. 4A, the battery compartment 200 can be sealed from leaks by inserting the cover 500 into the cover receptacle 310. As the cover 500 enters the cover receptacle 310 (as shown in FIG. 6A), the sealing element 600, and in particular, the ribs 630 of the sealing element 600, make contact with cover side wall 380. The end of each of the ribs 630 of the sealing element 600 is configured and sized to extend outwardly a distance slightly larger that the side wall 380 of the cover receptacle 310 to ensure that there is significant contact force between the sealing element 600 and the cover side wall 380. This contact force develops a frictional sealing force between the sealing element 600 and the container 300 to prevent leakage between the cover 500 and the container 300.

As shown in FIGS. 6A and 6B, as the cover 500 is pressed all the way into cover receptacle 380, all of the ribs 630 of the sealing element 600 come into frictional contact with cover side wall 380. The frictional forces developed are sufficient to prevent removal of the cover 500 by a child, even when no fasteners are used to secure the cover 500 to the battery compartment 200. Furthermore, the frictional force developed is sufficient to prevent easy removal even by an adult if only bare hands are used.

In addition, because the outer surface 510 of the cover 500 is aligned with the device wall 150 when cover 500 is installed, a user would have insufficient leverage to accidentally dislodge the cover 500. Furthermore, the frictional contact provides a leak-proof connection/seal between the cover 500 and the cover receptacle 380 such that substances (e.g., battery fluids) cannot escape the battery compartment 200.

In alternative embodiments, the battery compartment 200 need not be located above the child or in proximity to the electronic device 100. The benefits of the power source compartment of the present invention can be achieved regardless of the location of the power source compartment.

Alternative embodiments may include any children's product having an electrical or electronic feature powered by a portable power source. In other embodiments, for example, such as in the case of a swing having a motor that moves a child seat, the power source compartment could be positioned over or in proximity to a child.

In alternative embodiments the quantity of ribs provided on the sealing element may vary as well as the distance that the ribs extend outwardly from the body of the sealing element. In addition, the sealing element or sealing element portion may be integrally formed with the cover and the sealing element or sealing element portion may be the same or different material than that of the cover. In another embodiment, the electronic device may also include a seal between the cover and container that is formed by a sealing element on the container that has ribs that extend from the container sidewall to the cover. In such an embodiment, when the cover is placed in its closed position on the container, the ribs contact a side perimeter of the cover to form a seal.

In other embodiments, the shape or configuration of the cover and the cover receptacle can vary. In addition, the quantity of tab recesses formed in the housing and the corresponding quantity of tabs on the cover may vary.

Thus, it is intended that the present invention cover the modifications and variations of this invention that come within the scope of the appended claims and their equivalents. For example, it is to be understood that terms such as “left,” “right,” “top,” “bottom,” “front,” “rear,” “side,” “height,” “length,” “width,” “upper,” “lower,” “interior,” “exterior,” “inner,” “outer,” and the like as may be used herein, merely describe points of reference and do not limit the present invention to any particular orientation or configuration.

What is claimed is:

1. A power source compartment for use with an electronic device, the power source compartment comprising:
a container, the container defining a receptacle configured to receive a power source, the receptacle including an electrical portion configured to make electrical contact with the power source, the container also defining an opening through which the power source may be inserted into the receptacle, the opening having a perimeter, the container including a side wall extending around the perimeter of the opening;
a cover having an outer surface, an inner surface opposite its outer surface, and a side surface, the cover having a perimeter, the side surface extending substantially around the perimeter of the cover; and
a sealing element, the sealing element including an outer surface and an inner surface opposite its outer surface, the sealing element being disposed on the cover so that the sealing element inner surface engages the side surface of the cover, the sealing element including a plurality of ribs, the ribs extending around the outer surface of the sealing element and engaging the side wall of the container when the cover and sealing element are inserted into the opening of the container, the ribs being configured to seal the container and to frictionally couple the cover to the container.

2. The power source compartment of claim 1, wherein the ribs extend radially outward from the sealing element.

3. The power source compartment of claim 1, wherein the side surface of the cover includes a groove formed therein, the sealing element inner surface has a substantially planar configuration, and the sealing element inner surface has substantially the same configuration as the groove so that the sealing element inner surface mates with the groove of the cover side surface.

4. The power source compartment of claim 1, wherein the ribs of the sealing element extend outwardly beyond substantially all of the perimeter of the cover.

5. The power source compartment of claim 1, wherein the cover is coupled to the container only by the friction forces generated between the ribs and the container side wall.

6. A child entertainment device comprising:
a frame, the frame including a first side portion and an opposite second side portion, the frame defining an infant receiving region between the first side portion and the second side portion; and
an electronic system, the electronic system being supported on the frame and being disposed above the infant receiving region, the electronic system including:
a controller;
an output generating device, the output generating device being coupled to the controller and being configured to generate an output;
a power supply, the power supply being coupled to the controller; and
a power supply compartment, the power supply compartment including:
a container, the container defining a receptacle configured to receive a power supply, the receptacle including an opening through which the power supply may be inserted, the opening having a perimeter, the container including a side wall extending around the perimeter of the opening;
a cover including an outer surface, an inner surface opposite the outer surface, and a side surface, the cover having a perimeter, the side surface being disposed between the outer surface and the inner surface and extending around the perimeter of the cover; and
a sealing element, the sealing element including an outer surface and an inner surface opposite its outer surface, the sealing element being disposed on the cover so that the sealing element inner surface engages the side surface of the cover, the sealing element including a plurality of ribs formed in the sealing element outer surface and extending around the sealing element, the ribs engaging the side wall of the container when the cover and sealing element are inserted into the opening of the container, the ribs being configured to seal the container and to frictionally couple the cover to the container.

7. The child entertainment device of claim 6, wherein the power supply compartment is located above the infant receiving region defined by the frame.

8. The child entertainment device of claim 7, wherein the power supply compartment is leak-proof.

9. The child entertainment device of claim 6, wherein the side surface of the cover includes a groove formed therein, and the sealing element inner surface has the same configuration as the groove so that the sealing element inner surface mates with the groove of the cover side surface.

10. The child entertainment device of claim 6, wherein the ribs of the sealing element are configured to extend outwardly beyond substantially all of the perimeter of the cover.

11. The child entertainment device of claim 6, wherein the cover is coupled to the container only by the friction forces generated between the ribs and the container side wall.

12. The child entertainment device of claim 6, wherein the electronic system includes an entertainment component, the entertainment component being supported on the frame at a location above the infant receiving region, the entertainment component being configured to entertain a child disposed proximate to the infant receiving region.

13. The child entertainment device of claim 6, wherein the sealing element is made of a flexible material, the sealing element being configured to form a loop.

14. A child entertainment device comprising:
a frame, the frame including an upper portion and a lower portion, the lower portion being configured to provide support for the frame on a support surface, frame including a power supply compartment;
an electronic system, the electronic system including at least one input switch and at least one output device, the electronic system being configured to produce an output via the at least one output device in response to an input received by the at least one input switch, the electronic system including a power supply to power the electronic system, the power supply compartment defining a receptacle configured to receive the power supply and an opening through which the power supply may be inserted into the receptacle, the opening having a perimeter, the container including a side wall extending around the perimeter of the opening; and
a cover including a side surface extending substantially around a perimeter of the cover, the cover including a sealing element portion, the sealing element portion including at least one continuous rib formed in an outer surface of the sealing element and extending around the sealing element, the at least one rib engaging the side wall of the container when the cover is inserted into the opening of the container, the at least one rib being configured to seal the container and to frictionally couple the cover to the container.

15. The child entertainment device of claim 14, wherein the sealing element portion includes a plurality of ribs, and the ribs extend radially outward from the sealing element portion.

16. The child entertainment device of claim 14, wherein the cover has an outer surface, an inner surface opposite the outer surface, and a side surface, the side surface extending substantially around the perimeter of the cover, and the at least one rib being formed in the side surface.

17. The child entertainment device of claim 14, wherein the cover has a side surface, the side surface of the cover includes a groove formed therein, the sealing element portion includes an inner surface, and the sealing element portion inner surface has substantially the same configuration as the groove so that the inner surface of the sealing element portion mates with the groove of the cover side surface.

18. The child entertainment device of claim 16, wherein the cover is made of a first material and the sealing element portion is made of second material, the second material being different than the first material.

19. The child entertainment device of claim 14, wherein the cover is coupled to the container only by the friction forces between the ribs and the container side wall.

20. The child entertainment device of claim 14, wherein the cover includes a first mounting portion and a second mounting portion, each of the first mounting portion and the second mounting portion includes an opening therethrough, and each of the openings in the mounting portions is configured to receive a connector to couple the cover to the frame.
